(19) United States
(12) Patent Application Publication
(10) Pub. No.: US 2026/0292983 A1
(43) Pub. Date: Sep. 24, 2026

(54) WIRING SUBSTRATE

(71) Applicant: NITERRA CO., LTD., Nagoya-shi (JP)

(72) Inventors: Kota KIMATA, Nagoya-shi (JP); Junya MATSURA, Nagoya-shi (JP)

(21) Appl. No.: 19/559,518

(22) Filed: Mar. 6, 2026

(30) Foreign Application Priority Data
Mar. 21, 2025 (JP) 2025-046411

(51) Int. Cl. H05K 1/11

(52) U.S. Cl. CPC H05K 1/115

(57) ABSTRACT

A wiring substrate includes a resin layer having a pair of main faces and a through hole penetrating the resin layer in a thickness direction, and a via having electrical conductivity and filling the through hole. The via protrudes from the each of pair of main faces of the resin layer in the thickness direction and extends on each of the pair of main faces in a direction perpendicular to the thickness direction.

### CROSS-REFERENCE TO RELATED APPLICATIONS

The present application claims priority from Japanese patent application No. 2025-046411 filed on March 21, 2025, the entirety of the disclosure of which is incorporated herein by reference.

### BACKGROUND OF THE INVENTION

### 1. Field of the Invention

The present invention relates to a wiring substrate.

### 2. Description of the Related Art

There has been known a wiring substrate in which a plurality of resin layers are stacked on a ceramic substrate (see, for example, WO2015/102107). In the wiring substrate disclosed in WO2015/102107, electricity conducting portions formed on the respective surface of the resin layers are electrically connected by vias which penetrate the resin layers in the thickness direction thereof.

### SUMMARY OF THE INVENTION

In the case where a plurality of resin layers are stacked, electrical conduction, in the stacking direction, from the electricity conducting portion formed on the surface of each resin layer is established by bringing the electricity conducting portion into close contact with a via penetrating the resin layer. However, since no adhesion occurs between the via and the electricity conducting portion, the via and the electricity conducting portion are joined when the stacked resin layers are fused together. Therefore, in the case where the resin layers cannot be sufficiently brought into close contact with one another when they are bonded together, there arises the possibility that the via and the electricity conducting portion do not sufficiently come into close contact with each other, and thus, electrical conduction between the via and the electricity conducting portion is not secured. Although WO2015/102107 discloses a technique for suppressing shrinkage of the wiring substrate by forming a dummy conductor trace on the resin layers, the failure of connection between the electricity conducting portion formed on the surface of the resin layer and the via is not considered.

The present invention has been accomplished so as to solve at least partially the above-described problem, and an object of the present invention is to provide a technique for a wiring substrate in which a plurality of resin layers are stacked, the technique suppressing occurrence of a connection failure between an electricity conducting portion formed on the surface of each resin layer and a via penetrating the resin layer.

The present invention can be realized as the following aspect.

(1) According to one aspect of the present invention, a wiring substrate is provided. The wiring substrate includes a resin layer having a pair of main faces and a through hole penetrating the resin layer in a thickness direction; and a via having electrical conductivity and filling the through hole, wherein the via protrudes from each of the pair of main faces of the resin layer in the thickness direction and extends on each of the pair of main faces in a direction perpendicular to the thickness direction.

According to this configuration, portions of the via extend on the main faces of the resin layer in the direction perpendicular to the thickness direction. Therefore, the area of contact between the via and an electricity conducting portion formed on one of the main faces of the resin layer increases, and the bonding area of the via increases. As a result, a connection failure between the electricity conducting portion and the via is suppressed.

(2) In the wiring substrate of the above-described aspect, in a cross section parallel to the thickness direction, each of portions of the via, which portions extend on each of the pair of main faces, has a width which is 0.5 times or more of a diameter of the through hole.

According to this configuration, the via extends in sufficiently large regions on the main faces of the resin layer. Therefore, the reliability of joining between the via and the electricity conducting portion increases, and thus, stable electrical connection between the via and the electricity conducting portion is maintained.

The present invention can be realized in various aspects. For example, the present invention can be realized, for example, as a wiring substrate, an electronic component, a system including the wiring substrate and/or the electronic component, a method for manufacturing the wiring substrate, or a method for manufacturing the system including the wiring substrate and/or the electronic component.

### BRIEF DESCRIPTION OF THE DRAWING

FIG. 1 is a schematic sectional view of a wiring substrate according to one embodiment of the present invention.

### DESCRIPTION OF THE PREFERRED EMBODIMENT

### Embodiment

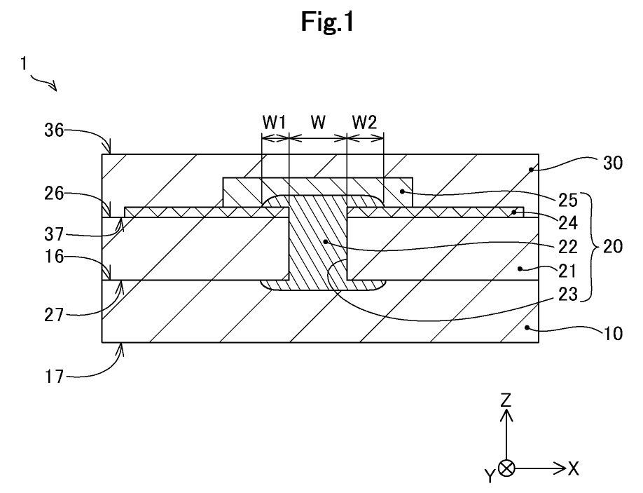

FIG. 1 is a schematic sectional view of a wiring substrate 1 according to one embodiment of the present invention. The wiring substrate 1 of the present embodiment is used for circuit formation of an electronic component, an IC package, a sensor device, a semiconductor manufacturing apparatus, or the like. Stacked three resin layers 10 to 30, which is a portion of the wiring substrate 1, are shown in FIG. 1. The three resin layers 10 to 30 are stacked in such a manner that the first resin layer 10, the second resin layer (a resin layer corresponding to the resin layer recited in the claims) 20, and the third resin layer 30 are stacked in this order in the stacking direction.

The first resin layer 10 has a pair of main faces 16 and 17. The second resin layer 20 is stacked on the main face 16 of the first resin layer 10 located on a Z-axis positive direction side. The second resin layer 20 includes a resin portion 21 having a pair of main faces 26 and 27, a via 22 which fills a through hole 23 penetrating the resin portion 21 in the thickness direction thereof, a copper foil 24 made of copper and formed on the main face 26, and an electricity conducting portion 25 formed on the copper foil 24. The third resin layer 30 has a pair of main faces 36 and 37. The first resin layer 10, the resin portion 21 of the second resin layer 20, and the third resin layer 30 are formed of the same material. The first resin layer 10, the second resin layer 20, and the third resin layer 30 are formed of a resin material such as polyimide.

A cross section of the through hole 23 of the second resin layer 20 perpendicular to the thickness direction has a constant circular shape. In the present embodiment, the diameter W of the through hole 23; i.e., the via 22 filling the through hole 23 is 30 micrometers. Notably, the schematic cross section shown in FIG. 1 is a cross section which passes through the center axis of the through hole 23.

As shown in FIG. 1, the via 22 protrudes in the thickness direction from each of the pair of main faces 26 and 27 of the resin portion 21. Moreover, the portion of the via 22 protruding from the main face 26 extends horizontally (i.e., perpendicularly to the stacking direction) on the copper foil 24 on the main face 26. Similarly, the portion of the via 22 protruding from the main face 27 extends horizontally on the main face 27. The electricity conducting portion 25 of the second resin layer 20 is connected to the upper surface of the via 22, which surface extends horizontally on the copper foil 24. The electricity conducting portion 25 is formed by applying a metal paste to the main face 26 of the resin layer 20 and performing firing. The metal paste contains, as a main component, copper, aluminum, silver, gold, platinum, nickel, titanium, iron, chromium, molybdenum, tungsten, or the like. The via 22 is formed by filling the through hole 23 with an electrically conductive paste containing copper or silver as a main component and performing firing. The main component is the component that accounts for 90% or more.

In the present embodiment, as shown in FIG. 1, a portion of the via 22, which portion extends on the main face 26 toward an X-axis negative direction side, has a width W1, and a portion of the via 22, which portion extends on the main face 26 toward an X-axis positive direction side has a width W2. In the present embodiment, in the cross section of the wiring substrate 1 shown in FIG. 1, the via 22 is formed in such a manner that, as represented by the following formular (1), the sum of the width W1 and the width W2 becomes 0.5 times or more of the diameter W of the through hole 23.

W1 + W2 ≥ 0.5W (1)

As described above, the second resin layer 20 of the wiring substrate 1 of the present embodiment includes the resin portion 21 having the pair of main faces 26 and 27, and the via 22 filling the through hole 23 penetrating the resin portion 21 in the thickness direction. As shown in FIG. 1, the via 22 protrudes from each of the pair of main faces 26 and 27 of the resin portion 21 in the thickness direction. Moreover, the portions of the via 22 protruding from each of the main faces 26 and 27 extend horizontally (perpendicularly to the stacking direction) on each of the main faces 26 and 27. Therefore, in the present embodiment, the area of contact between the via 22 and the electricity conducting portion 25 formed on the main face 26 of the second resin layer 20 increases, and the bonding area of the via 22 increases. As a result, a connection failure between the electricity conducting portion 25 and the via 22 is suppressed.

In addition, in the present embodiment, the via 22 is formed in such a manner that, in a cross section of the wiring substrate 1, the sum of the width W1 and the width W2 becomes 0.5 times or more of the diameter W of the through hole 23. In the present embodiment, since the via 22 extends in sufficiently large regions on the main faces 26 and 27 of the second resin layer 20, the reliability of joining between the via 22 and the electricity conducting portion 25 increases, and thus, stable electrical connection between the via 22 and the electricity conducting portion 25 is maintained.

### Modifications of the Present Embodiment

The present invention is not limited to the above-described embodiment and can be practiced in various forms without departing from the gist of the invention. For example, the following modifications are possible.

The wiring substrate 1 of the above-described embodiment is one example, and can be modified, provided that the via 22 protrudes in the thickness direction from each of the pair of main faces 26 and 27 of the second resin layer 20 and extends horizontally on each of the main faces 26 and 27. The materials used for forming the first resin layer 10, the resin portion 21 of the second resin layer 20, the third resin layer 30, the via 22, the electricity conducting portion 25, and the copper foil 24 can be changed within the range of known materials. For example, the copper foil 24 may be a film or layer formed of a metal other than copper. The main component of the copper foil 24 and the main component of the via 22 may differ from each other. The via 22 and the through hole 23 are not required to have a circular cross section. For example, the cross-sectional area of the via 22 may gradually change in the thickness direction of the second resin layer 20.

In the above-described embodiment, the electricity conducting portion 25 is formed on one main face 26 of the second resin layer 20. However, the electricity conducting portion 25 may be formed on the other main face 27 of the second resin layer 20. In addition, an electricity conducting portion may be formed on the main face 16 or 17 of the first resin layer 10 or the main face 36 or 37 of the third resin layer 30, and a via penetrating the first resin layer 10 or the third resin layer 30 may be formed.

In the above-described embodiment, as represented by the above-mentioned formular (1), the sum of the width W1 and the width W2 of the via extending on the main face 26 of the second resin layer 20 is 0.5 times or more of the diameter W of the through hole 23 or the via 22. However, the sum of the width W1 and the width W2 may be less than 0.5 times. The diameter W and the widths W1 and W2 may be determined, for example, by the following procedure. Specifically, the diameter W and the widths W1 and W2 are measured in a certain cross section which is parallel to the thickness direction and passes through the center axis of the through hole 23. Subsequently, the diameter W and the widths W1 and W2 are measured in three cross sections obtained by rotating the certain cross section by 45 degrees, 90 degrees, and 135 degrees, respectively, around the center axis of the through hole 23. The averages of the diameters W and the widths W1 and W2 in the four cross sections are used as the diameter W and the widths W1 and W2 in the second resin layer 20. It is preferred that the value of the smaller one of the widths W1 and W2 is 80% or more of the value of the larger one of the widths W1 and W2.

Although the present invention has been described on the basis of its embodiment and modifications, the above-described embodiment is provided so as to facilitate the understanding of the present invention and does not limit the present invention. The present invention can be changed or improved without departing from the purpose and the scope of the claims, and encompasses equivalents thereof. Also, the technical feature(s) may be eliminated unless the present specification mentions that the technical feature(s) is essential.

The present invention can be realized as the following modes.

### Application Example 1

A wiring substrate comprising:

a resin layer having a pair of main faces and a through hole penetrating the resin layer in a thickness direction; and

a via having electrical conductivity and filling the through hole, wherein

the via protrudes from each of the pair of main faces of the resin layer in the thickness direction and extends on each of the pair of main faces in a direction perpendicular to the thickness direction.

### Application Example 2

The wiring substrate described in the application example 1, wherein, in a cross section parallel to the thickness direction, each of portions of the via, which portions extend on each of the pair of main faces, has a width which is 0.5 times or more of a diameter of the through hole.

What is claimed is:

1. A wiring substrate comprising:
a resin layer having a pair of main faces and a through hole penetrating the resin layer in a thickness direction; and
a via having electrical conductivity and filling the through hole, wherein
the via protrudes from each of the pair of main faces of the resin layer in the thickness direction and extends on each of the pair of main faces in a direction perpendicular to the thickness direction.

2. The wiring substrate according to claim 1, wherein, in a cross section parallel to the thickness direction, each of portions of the via, which portions extend on each of the pair of main faces, has a width which is 0.5 times or more of a diameter of the through hole.
